(19) United States
(12) Patent Application Publication
(10) Pub. No.: US 2006/0003483 A1
(43) Pub. Date: Jan. 5, 2006

(54) Optoelectronic packaging with embedded window

(76) Inventors: Larry Lee Wolff, Pak Kret (TH); Wichai YansaLee, Thanyaburi (TH)

Correspondence Address: BRUCE E. WEIR, 12 SPARROW VALLEY COURT, MONTGOMERY VILLAGE, MD, 20886-1265, US

(21) Appl. No.: 11/212,461

(22) Filed: Aug. 27, 2005

Related U.S. Application Data
(63) Continuation-in-part of application No. 10/613,089, filed on Jul. 7, 2003.

(51) Int. Cl. H01L 21/00

(52) U.S. Cl. 438/65

(57) ABSTRACT

A method and apparatus for encapsulating optoelectronic components. An optical semiconductor die is attached to a lead frame or a substrate. A solid window transparent to light and no larger than the die area, excluding wire bond pads, is cut, scored, or otherwise singulated from glass or plastic. A transparent adhesive is applied to the optically-sensitive portion of the die, then the window is placed on the optically-sensitive portion of the die by a pick-and-place machine, forming a transparent aperture. Flexible support strips allow a die paddle to move during component assembly. Wires connect die circuitry to electrical leads on the lead frame or substrate. The assembly is encapsulated in molding material, leaving the upper surface of the window and the electrical leads exposed.

### CROSS-REFERENCE TO RELATED APPLICATION

This application is a continuation-in-part of U.S. patent application Ser. No. 10/613,089, filed Jul. 7, 2003 by the same inventors, now pending.

### FIELD OF THE INVENTION

The present invention relates to the packaging of optical semiconductor or optoelectronic devices.

### BACKGROUND OF THE INVENTION

Optical semiconductors are key components in a wide variety of electronic devices. Because optical semiconductors are fragile and subject to damage by impact, abrasion, contaminants, moisture, heat, and other factors, each optical semiconductor is typically encased in a protective package. However, unlike the protective packages used to encase most other electronic components, the package for an optical semiconductor must incorporate a region that is transparent to light.

It has been a common practice to create an optoelectronic sensor package by mounting a sensor within a ceramic container with embedded conductive leads, then sealing the container with a window made of optical glass. The window does not directly contact the sensor, instead leaving some air space between the window and the sensor.

While this method can produce a relatively rugged sensor package with good optical properties, the enclosed space between the window and the die may contain moisture that can condense within the package. The enclosed space also adds at least two boundary layers to the light path, possibly resulting in unwanted reflection, refraction, or dispersion of light. These undesirable effects may be intensified if the plate is not parallel to the die surface.

Therefore, the requirements for extremely clean manufacturing conditions, humidity control within the container, and precise sensor die positioning with respect to the window often result in a packaged sensor that is bulky and expensive, sometimes accounting for half the total cost of a finished product.

Recent improvements in adhesives and manufacturing technology have made possible the simultaneous fabrication of large numbers of identical sensor packages in which the window is bonded directly to the die, thereby eliminating enclosed air space. This is accomplished by bonding a single sheet of suitable window material to an array of optical semiconductors, then cutting the sheet to separate the individual packages. Low-cost plastic encapsulation material may be used to seal portions of the die that remain exposed.

While this method mitigates many of the problems arising from inclusion of an air space between a window and a die, the resulting package may retain a considerable amount of unusable window material, which, being heavy and expensive relative to plastic encapsulation materials typically used to complete the package, adds unwanted weight and cost to the finished product. Further, every window produced in a given production run is essentially the same, limiting the manufacturer's ability to adapt to market demands by economically producing small numbers of sensor packages with windows having different characteristics.

What is needed, then, is a method for manufacturing a packaged optoelectronic sensor that reduces the bulk and cost of the packaged sensor while providing adequate protection for the die and mitigating the problems arising from space between the window and die. Windows should be placed and bonded individually, allowing flexibility in the manufacturing process. The method should utilize standard manufacturing equipment and raw materials.

### SUMMARY OF THE INVENTION

The present invention is a manufacturing method that utilizes standard manufacturing equipment and raw materials to produce compact, low-cost packaged optoelectronic components such as Erasable Programmable Read Only Memory (EPROM) chips, Electrically Erasable Programmable Read Only Memory (EEPROM) chips, Charge-Coupled Device (CCD) chips, Complementary Metal Oxide Semiconductor (CMOS) chips, and other optical semiconductor devices that are known in the art.

In a preferred embodiment of the present invention an aperture member is created from optical glass, plastic, or other materials that are transparent to the radiation spectra of interest. The material may be selected to absorb or pass specific radiation frequencies. An aperture member is typically cut from a plate of suitable material by a sawing, dicing, or scribing process, although other known processes may be used. The aperture member may be shaped, scored, or otherwise modified to refract, diffract, or diffuse light passing through. The aperture member may be sized and shaped to cover any portion of a semiconductor die, but is preferably sized to cover only the optically-sensitive portion of the die. Since the aperture member is individually manufactured, it may be of any suitable thickness and may have a horizontal cross-section of any suitable shape.

A semiconductor die with an optically-sensitive portion is then mounted on a lead frame. A computer-controlled pick-and-place machine selects an aperture member with desired characteristics. Pick-and-place machines are standard semiconductor manufacturing devices and may be programmed to select and precisely place a different component from one operation to the next. A transparent adhesive is applied to the aperture member, or to the die, or to both, then the pick-and-place machine positions the aperture member over the optically-sensitive portion of the die. The aperture member is pressed against the die, allowing the transparent adhesive to bond the aperture member to the die. The transparent adhesive may be an epoxy, silicon, tape, or other adhesive materials that are known in the art.

Since the aperture member is attached directly to the die, no intervening air space remains to produce condensation or unwanted reflection, refraction, or diffusion. Since the aperture member is pre-sized and pre-shaped to cover the optically-sensitive portion of the die, the surfaces of the aperture member are automatically made parallel to the die surface upon installation and require no further cutting. Both the aperture member material and the transparent adhesive may be selected for desired refractive index, absorption, or other physical characteristics. The assembly is encapsulated with an epoxy molding compound or other encapsulate as is known in the art, leaving the leads and the upper portion of the aperture member exposed.

In an alternate embodiment of the present invention, a semiconductor die with an optically-sensitive area may be mounted with an adhesive material on a Printed Circuit Board (PCB) or ceramic substrate. The adhesive material may be a silver-filled epoxy, a polyimide epoxy, a thermally-conductive epoxy, a thermally or electrically non-conductive epoxy, an adhesive tape, or a metal alloy.

Metal wires such as gold, aluminum, or copper are bonded between the semiconductor die and the active circuitry on the substrate. A transparent adhesive is applied to the semiconductor die or to an aperture member made of borosilicate glass or another suitable material known in the art. The aperture member is placed on the optically-sensitive portion of the die by a pick-and-place machine. The assembly is baked. The die, aperture member, and substrate are encapsulated with an epoxy molding compound. Finally, the individual die package is separated from any attached frame or substrate and visually inspected.

### DESCRIPTION OF THE DRAWINGS

FIG. 1 shows a perspective view of an encapsulated optoelectronic device.

FIG. 2 shows a cutaway view of the encapsulated optoelectronic device of FIG. 1, revealing portions of a lead frame, semiconductor die, and embedded aperture member.

FIG. 3 is a cross-sectional view of the encapsulated optoelectronic device of FIG. 1.

FIGS. 4A through 4E are cross-sectional views showing the assembly of a Through Hole Device (THD) package.

FIGS. 5A through 5E are cross-sectional views showing the assembly of a Surface Mount Device (SMD) package.

FIGS. 6A through 6E are cross-sectional views showing the assembly of a Plastic Non-Leaded package.

FIGS. 7A through 7F ate cross-sectional views showing the assembly of a package with a substrate, such as a Land Grid Array (LGA) or a Ball Grid Array (BGA) package.

FIG. 8A is a plan view of a die paddle with flexible support strips attached.

FIGS. 8B through 8F are cross-sectional views showing the assembly of a Through Hole Device (THD) package with flexible support strips attached to the die paddle.

FIG. 9A shows a plan view of a portion of a lead frame.

FIG. 9B shows an enlarged view of four adjacent die paddle assemblies.

FIG. 9C shows a cross-sectional elevation view of the die paddle assemblies of FIG. 9B.

FIG. 9D shows another cross-sectional elevation view of the die paddle assemblies of FIG. 9B, with the vertical dimensions of the die paddles and metal contacts somewhat exaggerated for clarity.

FIG. 9E shows a cross-sectional elevation view of components assembled on the die paddle assemblies of FIG. 9D.

FIG. 9F shows a portion of a plan view of a mold tool.

FIG. 9G shows a cross-sectional elevation view of the mold tool of FIG. 9F.

FIG. 9H shows a portion of a cross-sectional elevation view after component assemblies are enclosed by a mold tool.

FIG. 9J shows a cross-sectional elevation view of a singulated optoelectronic package.

FIG. 9K shows a cross-sectional perspective view of a singulated optoelectronic package.

### DETAILED DESCRIPTION OF THE INVENTION

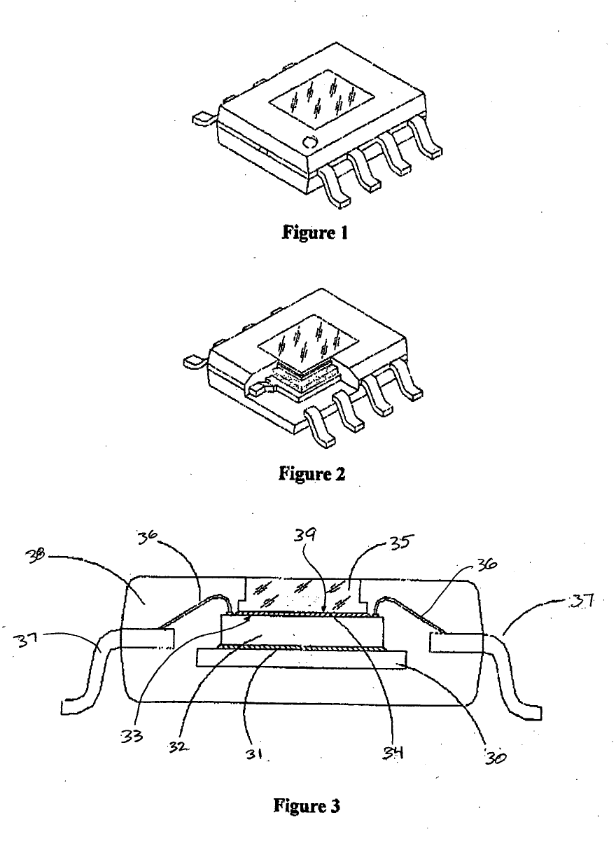

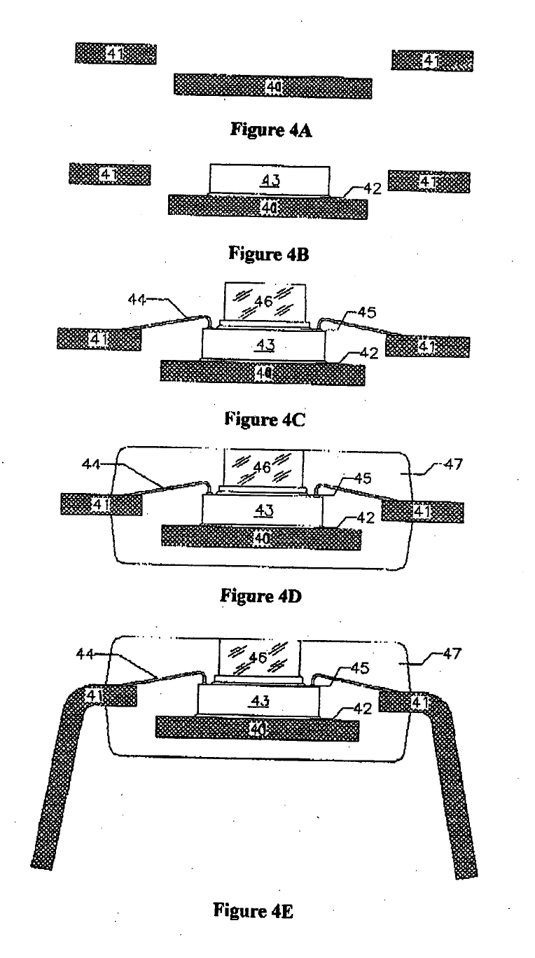

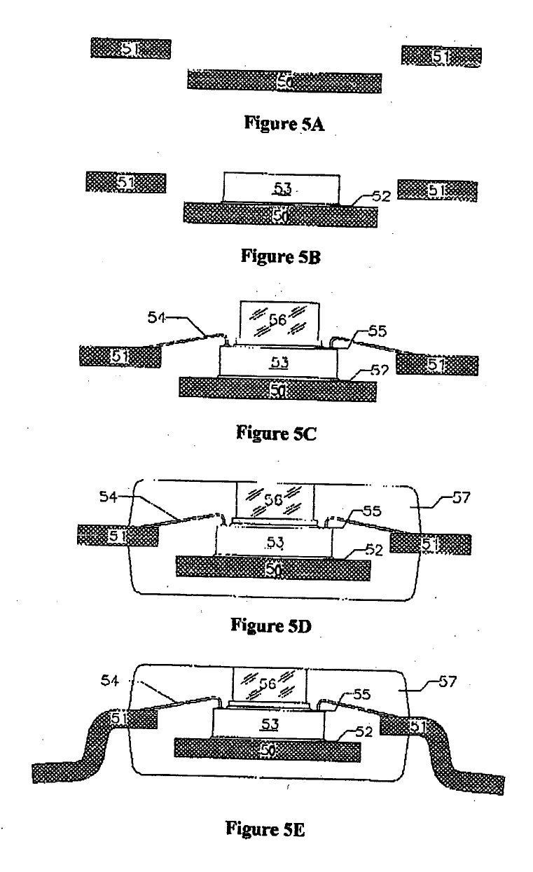

FIGS. 1, 2, and 3 show different views of an embodiment of the present invention. FIG. 1 shows a perspective view of an encapsulated optoelectronic device. FIG. 2 shows a cutaway view of the same device, revealing portions of a lead frame, semiconductor die, and embedded aperture member. FIG. 3 is a cross-sectional view of the same device. In FIG. 3, an optical semiconductor die 32 is secured upon a die paddle 30 with an adhesive epoxy material 31 or other bonding agent known in the art. Metal wires 36 are bonded from semiconductor die 32 to external metal leads 37, which connect the circuitry of the semiconductor die 32 to external circuitry (not shown).

A transparent adhesive 34 is then applied to the optically active upper surface 33 of the semiconductor die 32. An aperture member 35 made of borosilicate glass or other suitable material known in the art is placed by a pick-and-place machine on the upper surface of transparent adhesive 34, affixing the aperture member 35 to the transparent adhesive 34 and the optically active upper surface 33 of the semiconductor die 32, forming a transparent aperture above the optically active upper surface 33. The pick-and-place machine may according to its programming instructions select an aperture member with any desired characteristics. Since in accordance with the method of the present invention each aperture member is individually placed and affixed to a semiconductor die, the pick-and-place machine may select a different type of aperture member for each of any number of sequentially-assembled optoelectronic packages.

An aperture member may be created from optical glass, plastic, or other materials that are transparent to the radiation spectra of interest. The material may be selected to absorb or pass specific radiation frequencies. An aperture member is usually cut from a plate of suitable material by a sawing, dicing, or scribing process, although other known processes may be used. The aperture member may be shaped, scored, or otherwise modified to refract, diffract, or diffuse light passing through. The aperture member may be sized and shaped to cover any portion of a semiconductor die, but is preferably sized to cover only the optically-sensitive portion of the die. Since the aperture member is individually manufactured, it may be of any suitable thickness and may have a horizontal cross-section of any suitable shape.

No open space is left between the semiconductor die 32 and the aperture member 35 after the two parts are bonded. An epoxy molding compound or other encapsulate as is known in the art is formed around the die paddle 30, semiconductor die 32, and aperture member 35, leaving the upper surface of the aperture member 35 and the external metal leads 37 exposed.

In an alternate embodiment of the present invention, the transparent adhesive 34 may be applied to a lower surface 39 of the aperture member 35, with the lower surface 39 of the aperture member 35 then being positioned by a pick-and-place machine against the optically active upper surface 33 of the semiconductor die 32.

In still another embodiment of the present invention the order of assembly steps may be varied. A transparent adhesive 34 is applied to the optically active upper surface 33 of the semiconductor die 32. An aperture member 35 made of borosilicate glass or another suitable material as is known in the art is placed by a pick-and-place machine on the optically active upper surface 33 of the semiconductor die 32 and affixed to the transparent adhesive 34, forming a transparent aperture above the optically active upper surface 33. No open space is left between the semiconductor die 32 and the aperture member 35 after the two parts are bonded.

An optical semiconductor die 32 is then secured upon a die paddle 30 with an adhesive epoxy material 31 or other bonding agent known in the art. Metal wires 36 are bonded from semiconductor die 32 to external metal leads 37, which connect the circuitry of the semiconductor die 32 to external circuitry (not shown). An epoxy molding compound or other encapsulate as is known in the art is formed around the die paddle 30, semiconductor die 32, and aperture member 35, leaving the upper surface of the aperture member 35 and the external metal leads 37 exposed.

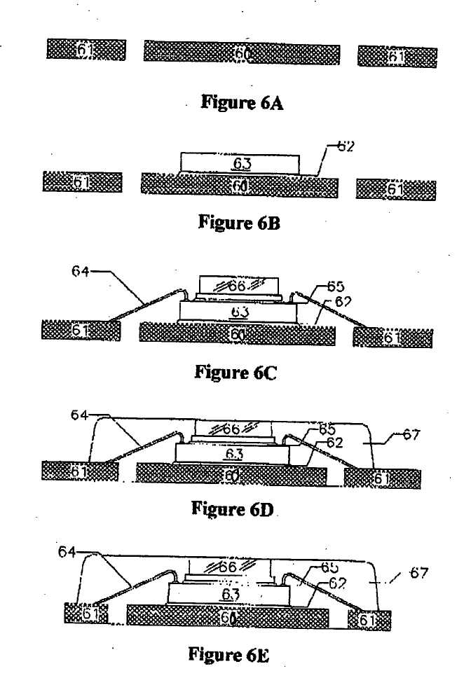

FIGS. 4A through 4E show the assembly of a preferred embodiment of the present invention. FIG. 4A shows a cross-sectional view of a metal lead frame as is known in the art, with a die paddle 40 and metal leads 41. The lead frame is configured to accommodate a desired semiconductor and related electrical circuitry.

FIG. 4B shows a semiconductor die 43 attached by an adhesive material 42 to the upper surface of the die paddle 40. The adhesive material 42 may be dispensed, stamped, laminated, or applied by other means known in the art atop the die paddle 40. The adhesive material 42 can be a silver-filled epoxy, a polyimide epoxy, a thermally-conductive epoxy, a thermally or electrically nonconductive epoxy, an adhesive tape, or a metal alloy. The adhesive material 42 is heated and cured, thereby securing the semiconductor die 43 to the die paddle 40.

In FIG. 4C, metal wires 44 are bonded between the semiconductor die circuitry (not shown) and the metal leads 41, connecting the die circuitry to external circuitry (not shown). The metal wires 44 may comprise gold, aluminum, copper or other suitable materials as are known in the art. An aperture member 46 is attached upon an optically-sensitive area of the die with a transparent adhesive material 45. The transparent adhesive material 45 may be dispensed, stamped, laminated, or applied by other means known in the art to either upper surface of the semiconductor die 43 or the lower surface of the aperture member 46.

FIG. 4D shows a cross-sectional view of the present invention after the die paddle 40, the semiconductor die 43, and aperture member 46 are encapsulated with an epoxy molding compound as is known in the art, forming a package 47 while leaving the upper surface of the aperture member 46 and the metal leads 41 exposed.

FIG. 4E shows the exposed metal leads 41 formed at approximately a 90-degree angle with respect to the plane of the die paddle 41, creating a device especially suited for application as a Through Hole Device (THD) such as a Plastic Dual-Inline Package (PDIP). Finally, the individual package is punched out or cut from any attached metal frame to become a finished package.

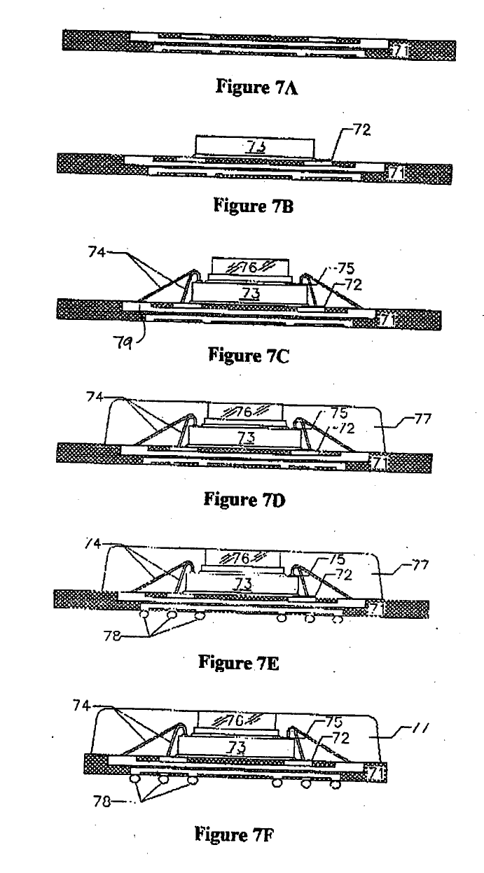

FIGS. 5A through 5E show the assembly of an embodiment similar to that shown in FIGS. 4A through 4E, except that in FIG. 5E the exposed parts of the metal leads 51 may be formed as a gull wing, a J-form, or a C-form as required by external circuitry, creating a device especially suited for use as a Surface Mount Device (SMD) package such as a Plastic Leaded Chip Carrier (PLCC), a Small Outline Plastic (SOP), a Small Outline Integrated Circuit (SOIC), or a Plastic Quad Flat Pack (PQFP).

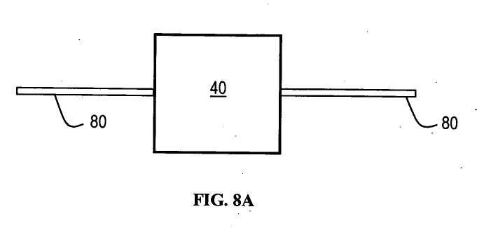

FIGS. 6A through 6E show the assembly of an embodiment especially suited to non-leaded surface mount applications such as a Plastic non-Leaded Package (PLLP). FIG. 6A shows a cross-sectional view of a metal frame as is known in the art, with a die paddle 60 and metal contacts 61. The frame is configured to accommodate a desired semiconductor and related electrical circuitry.

FIG. 6B shows a semiconductor die 63 attached by an adhesive material 62 to the upper surface of the die paddle 60. The adhesive material 62 may be dispensed, stamped, laminated, or applied by other means known in the art atop the die paddle 60. The adhesive material 62 can be a silver-filled epoxy, a polyimide epoxy, a thermally-conductive epoxy, a thermally or electrically nonconductive epoxy, an adhesive tape, or a metal alloy. The adhesive material 62 is heated and cured, thereby securing the semiconductor die 63 to the die paddle 60.

In FIG. 6C, metal wires 64 are bonded between the semiconductor die circuitry (not shown) and the metal contacts 61, connecting the die circuitry to external circuitry (not shown). The metal wires 64 may comprise gold, aluminum, copper or other suitable materials as are known in the art. An aperture member 66 is attached upon an optically-sensitive area of the die with a transparent adhesive material 65. The transparent adhesive material 65 may be dispensed, stamped, laminated, or applied by other means known in the art to either upper surface of the semiconductor die 63 or the lower surface of the aperture member 66.

FIG. 6D shows a cross-sectional view of the present invention after the semiconductor die 63, the aperture member 66, and the upper portions of the die paddle 60 are encapsulated with an epoxy molding compound as is known in the art, forming a package 67 while leaving the upper surface of the aperture member 66 and lower surfaces of the metal contacts 61 exposed. Finally, as shown in FIG. 6E, the individual package is punched out or cut from any attached frame to become a finished package.

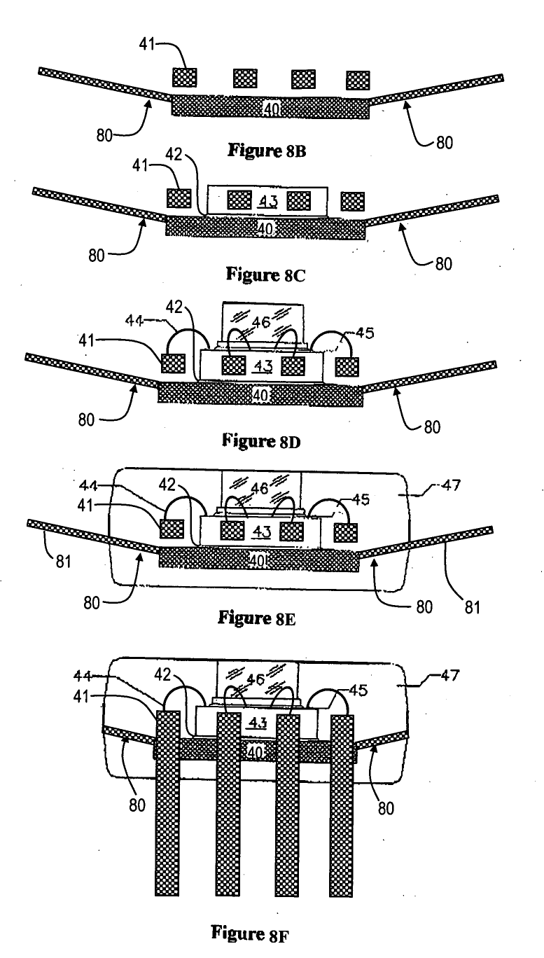

FIGS. 7A through 7E show the assembly of an embodiment especially suited for Ball Grid Array (BGA) or Land Grid Array (LGA) packages. As shown in FIG. 7A, a Printed Circuit Board (PCB) substrate 71 comprising rubber, bismallimide triazene (BT), a ceramic, or other suitable material as is known in the art is configured to accommodate a desired semiconductor and related electrical circuitry.

FIG. 7B shows a semiconductor die 73 attached by an adhesive material 72 to the upper surface of the substrate 71. The adhesive material 72 may be dispensed, stamped, laminated, or applied by other means known in the art atop the substrate 71. The adhesive material 72 can be a silver-filled epoxy, a polyimide epoxy, a thermally-conductive epoxy, a thermally or electrically nonconductive epoxy, an adhesive tape, or a metal alloy. The adhesive material 72 is heated and cured, thereby securing the semiconductor die 73 to the substrate 71.

In FIG. 7C, metal wires 74 are bonded between the PCB circuitry 79 and the semiconductor die circuitry (not shown). The metal wires 74 may comprise gold, aluminum, copper or other suitable materials as are known in the art. An aperture member 76 is attached upon an optically-sensitive area of the die with a transparent adhesive material 75. The transparent adhesive material 75 may be dispensed, stamped, laminated, or applied by other means known in the art to either upper surface of the semiconductor die 73 or the lower surface of the aperture member 76.

FIG. 7D shows a cross-sectional view of the present invention after the semiconductor die 73, the aperture member 76, and the upper portions of the substrate 71 are encapsulated with an epoxy molding compound as is known in the art, forming a package 77 while leaving the upper surface of the aperture member 76 and lower surfaces of the substrate 71 exposed.

FIG. 7E shows attachment of solder balls 78 to terminals on the lower side of the substrate 71 for a BGA package. The solder balls 78 are not required on an LGA package. Finally, the individual package is punched out or cut from any attached substrate to become a finished package.

As previously described, the optical member, semiconductor die, and die paddle of each embodiment of the present invention are bonded together directly with thin layers of adhesives, so that during sensor assembly each component is properly aligned with adjacent components without need for rings, ridges, bumps, or other component alignment features known in the art. The simplicity of this method allows a manufacturer considerable latitude in the dimensions and size variances of components. This latitude may be enhanced in many embodiments of the present invention by the use of flexible die paddle support strips.

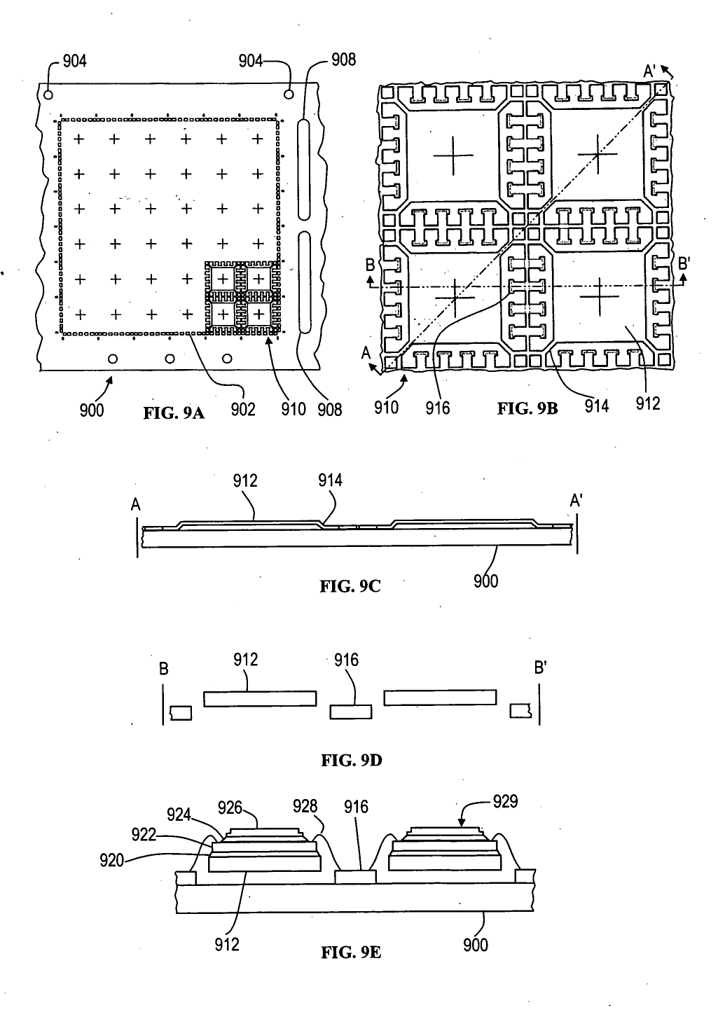

FIG. 8A shows an alternate embodiment of the die paddle 40 of the embodiment of FIGS. 4A through 4E with die paddle support strips 80 attached. FIG. 8A shows the die paddle 40 with two support strips 80, each attached near the center of an opposing side of the die paddle 40. Support strips are formed or attached prior to sensor assembly in any quantity or position deemed suitable for a particular sensor manufacturing operation. Support strips may be formed directly from a die paddle while or after the die paddle is stamped or wet-etched from a copper sheet. Alternatively, support strips may be attached using adhesives or other methods known in the art.

FIGS. 8B through 8E show a sensor assembly that is essentially the same as that already described in FIGS. 4A through 4E and FIGS. 5A through 5E, with the addition of support strips 80. The same assembly process is used, with the addition of a trimming operation. During sensor assembly the support strips 80 are supported by a mold tool (not shown) as is known in the art. As shown in FIG. 8E, the support strips protrude from the package 47 after the package 47 is molded. The protruding ends 81 are trimmed to be approximately flush with the surface of the package 47, resulting in the finished sensor shown in FIG. 8F.

The support strips 80 are usually made from thin copper sheet metal, although other metals or plastics or ceramics might be utilized for specific material characteristics. Since the support strips 80 are flexible, the presence of the support strips 80 during the assembly steps shown in FIGS. 8B, 8C, and 8D allows the die paddle 40 to move during component assembly in response to variations in the thickness of the die paddle 40, semiconductor die 43, optical member 46, adhesive material 42, transparent adhesive material 45, and mold tools (not shown). Die paddle 40 motion during component assembly allows components to settle into optimum positions without the use of alignment structures. A manufacturer may then use components with greater dimensional variances while still producing sensor packages with required optical characteristics. A manufacturer may also use increased assembly pressure without damaging components. In a preferred embodiment, the die paddle 40 may be deflected up to 0.002 inch toward the lead frame.

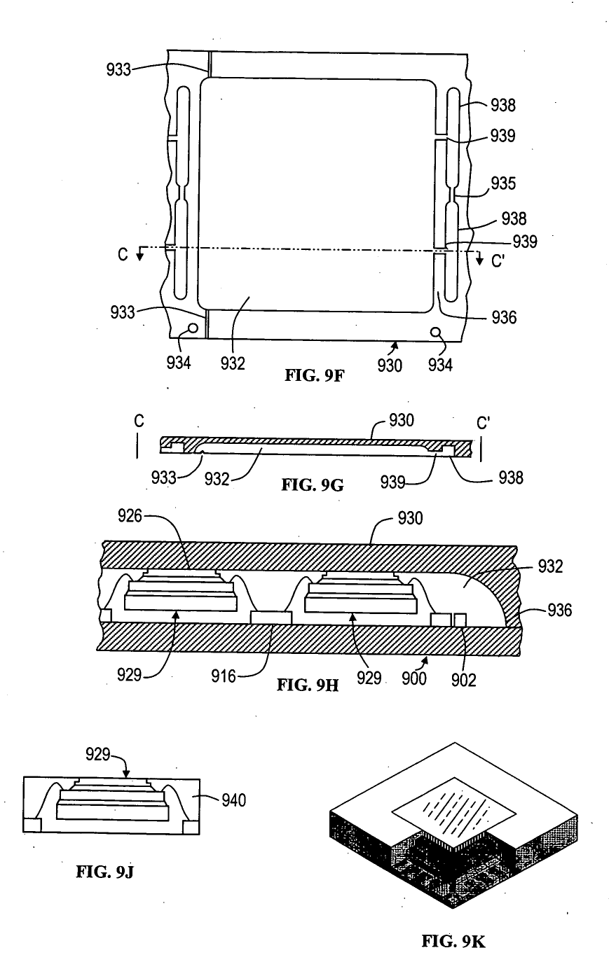

FIGS. 9A through 9K show the assembly of an alternate embodiment of the PLLP non-leaded surface mount application shown in FIGS. 6A through 6F. The process may be applied to BGA, PCB, LGA, and other QFN assemblies. FIG. 9A shows a plan view of a portion of a lead frame 900. In this embodiment the lead frame 900 is a flat plate made of materials known in the art. Die paddle assembly location pins 902 on the lead frame 900 form a perimeter that locates die paddle assemblies 910 upon the lead frame 900. FIG. 9A shows four adjacent die paddle assemblies 910 disposed upon the lead frame 900, but in a typical application the entire area within the die paddle assembly location pins 902 would be populated by similar die paddle assemblies 910.

Lead frame runner slots 908 mate with mold tool runner slots 938 shown in FIG. 9F. Mold tool location pins 904 mate with mold tool location holes 934 in the mold tool 930 shown in FIG. 9F.

FIG. 9B shows an enlarged view of four adjacent die paddle assemblies 910. Die paddles 912 are supported by support strips 914 projecting diagonally from each corner of a die paddle 912. Support strips 914 may be formed as a die paddle assembly 910 is stamped or wet-etched from a copper sheet, with the die paddle 912 simultaneously or subsequently formed upward or downward with respect to the plane of the metal contacts 916. Although FIG. 9A shows a lead frame 900 having space for thirty-six component assemblies, a lead frame 900 may have space for any number of die paddle assemblies 910 allowed by the manufacturing system used.

FIG. 9C shows a cross-sectional elevation view of the die paddle assemblies 910 of FIG. 9B. Each die paddle 912 is supported at each corner by support strips 914 that raise the die paddle 912 above the lead frame 900. As described above for the embodiments of FIG. 8, the support strips 914 are usually made from thin copper sheet metal, although other metals or plastics or ceramics might be utilized for specific material characteristics. Since the support strips 914 are flexible, the presence of the support strips 914 during the component assembly allows a die paddle 912 to move in response to variations in the thickness of the die paddle 912, semiconductor die, optical member, adhesive material, transparent adhesive material, and mold tool. In a preferred embodiment, the die paddle 912 may be deflected up to 0.002 inch toward the lead frame 900. Die paddle 912 motion during component assembly allows components to settle into optimum positions without the use of alignment structures. A manufacturer may then use components with greater dimensional variances while still producing sensor packages with required characteristics. A manufacturer may also use increased assembly pressure without damaging components. Attachment of support strips 914 to each corner of a die paddle 912 reduces undesirable die paddle positional deviations that may occur when only two support strips are used.

FIG. 9D shows another cross-sectional elevation view of the die paddle assemblies 910 of FIG. 9B, with the vertical dimensions of the die paddles 912 and metal contacts 916 somewhat exaggerated for clarity.

FIG. 9E shows a cross-sectional elevation view of components assembled on the die paddle assemblies of FIG. 9D. A semiconductor die 922 is attached by an adhesive material 920 to the upper surface of the die paddle 912. A pick-and-place machine as is known in the art may according to its programming instructions select a semiconductor die 922 with any desired characteristics. Since in accordance with the method of the present invention each semiconductor die 922 is individually placed and affixed to a die paddle 912, the pick-and-place machine may select a different type of semiconductor die 922 for each of any number of sequentially-assembled optoelectronic packages.

The adhesive material 920 may be dispensed, stamped, laminated, or applied by other means known in the art atop the die paddle 912. The adhesive material 920 can be a silver-filled epoxy, a polyimide epoxy, a thermally-conductive epoxy, a thermally or electrically nonconductive epoxy, an adhesive tape, or a metal alloy. The adhesive material 920 is heated and cured, thereby securing the semiconductor die 922 to the die paddle 912. Metal wires 928 are bonded between the semiconductor die circuitry (not shown) and the metal contacts 916, connecting the die circuitry to external circuitry (not shown). The metal wires 928 may comprise gold, aluminum, copper or other suitable materials as are known in the art. In preferred embodiments, silver may be selectively plated on portions of the die paddle 912 and metal contacts 916 requiring gold bonds. Since mold compound does not adhere to silver, silver plating is avoided in other areas.

FIG. 9E additionally shows an aperture member 926 as previously described, attached in a manner previously described upon an optically-sensitive area of the semiconductor die 922 with a transparent adhesive material 924 as is known in the art. The transparent adhesive material 924 may be dispensed, stamped, laminated, or applied by other means known in the art to either upper surface of the semiconductor die 922 or the lower surface of the aperture member 926. The metal contacts 916, metal wires 928, die paddle 912, adhesive material 920, semiconductor die 922, transparent adhesive material 924, and aperture member 926 together comprise a component assembly 929.

FIG. 9F shows a portion of a plan view of a mold tool 930 with a mold cavity 932 and mold tool location holes 934. FIG. 9G shows a cross-sectional elevation view of the mold tool of FIG. 9F. Once components are assembled as shown in FIG. 9E, the mold tool 930 is placed on the lead frame 900 with the mold cavity 932 facing the lead frame 900. The mold tool 930 and lead frame 900 are aligned by mating mold tool location pins 904 with mold tool location holes 934. Mold tools 930 with mold cavities 932 of different depths may be used to accommodate different component assemblies 929.

Epoxy molding compound as is known in the art is injected through the lead frame runner slots 908 into the mold tool runner slots 938, with pressure and molding compound distribution equalized between mold tool runner slots 938 by an equalizing channel 935 in the mold tool 930. Molding compound then passes through gates 939 into the mold cavity 932 and envelopes the die paddles and assembled components. Air is forced out of the mold cavity 932 through vents 933 (FIG. 9A). Vents 933 exit the perimeter of the mold cavity 932 so that residual molding compound protruding into a vent may later be trimmed off during a routine trimming process. Vents 933 are preferentially of a significantly smaller diameter than gates 939 to limit the escape of molding compound.

FIG. 9H shows a portion of a cross-sectional elevation view of the present invention after the component assemblies 929 are enclosed by the mold tool 930. The edges 936 of the mold cavity 932 contact the lead frame 900 outside of the die paddle assembly location pins 902, mating closely enough to the lead frame 900 to minimize leakage of molding compound. Injected molding compound encapsulates all components except the lower surfaces of the metal contacts 916 and the upper surfaces of the aperture members 926. The mold tool 930 is then removed, the encapsulated component assemblies 929 are removed from the lead frame 900, and individual component assemblies are singulated and trimmed with a saw or water-assisted laser to form individual optoelectronic packages as shown in FIG. 9J. FIG. 9K shows a cross-sectional perspective view of a singulated optoelectronic package.

The embodiments described above utilize pre-cut aperture members rather than wafer-sized sheets, eliminating extra cutting steps and allowing increased flexibility in selecting the size, position, and optical characteristics of each embedded window. An aperture member 926 made of borosilicate glass or other suitable material known in the art is placed by a pick-and-place machine on the upper surface of transparent adhesive 924, affixing the aperture member 926 to the transparent adhesive 924 and the optically active upper surface of the semiconductor die 922, forming a transparent aperture above the optically active upper surface. The pick-and-place machine may according to its programming instructions select an aperture member with any desired characteristics. Since in accordance with the method of the present invention each aperture member is individually placed and affixed to a semiconductor die, the pick-and-place machine may select a different type of aperture member for each of any number of sequentially-assembled optoelectronic packages.

The principles, embodiments, and modes of operation of the present invention have been set forth in the foregoing specification. The embodiments disclosed herein should be interpreted as illustrating the present invention and not as restricting it. For example, it should be recognized that a lead frame might be replaced with a printed circuit board (PCB) or a wired circuit board (WCB), and that an optoelectronic sensor might be replaced by a light-emitting semiconductor. Additionally, the assembly steps may be varied from the orders described, and in each case prior to assembly the transparent adhesive may be applied first to the aperture member or to both the die and the aperture member. In any embodiment of the present invention a pick-and-place machine may select a different type of semiconductor die and/or aperture member for each of any number of sequentially-assembled optoelectronic packages.

The foregoing disclosure is not intended to limit the range of equivalent structure available to a person of ordinary skill in the art in any way, but rather to expand the range of equivalent structures in ways not previously contemplated. Numerous variations and changes can be made to the foregoing illustrative embodiments without departing from the scope and spirit of the present invention.

We claim:

1. A method comprising:
bonding an optical semiconductor element to a die paddle, the die paddle supported by at least one flexible support strip, the optical semiconductor element having a radiation-sensitive portion;
applying a transparent adhesive element to at least the radiation-sensitive portion; and
applying an aperture member to the transparent adhesive element.

2. A method comprising:
bonding an optical semiconductor element to a die paddle, the die paddle supported by at least one flexible support strip, the optical semiconductor element having a radiation-sensitive portion;
applying a transparent adhesive element to at least the radiation-sensitive portion;
selecting an aperture member; and
applying the aperture member to the transparent adhesive element.

3. A method as claimed in claim 2, wherein the aperture member is selected for a least one physical characteristic.

4. A method as claimed in claim 2, wherein the aperture member is selected and applied to the transparent adhesive element by a programmable pick-and-place semiconductor assembly machine.

5. A method as claimed in claim 2, wherein the optical semiconductor element is selected and placed by a programmable pick-and-place semiconductor assembly machine.

6. A method as claimed in claim 2, wherein the optical semiconductor element is bonded to the lead frame with a bonding agent selected from the group consisting of a silver-filled epoxy, a polyimide epoxy, a thermally conductive epoxy, a thermally nonconductive epoxy, an electrically nonconductive epoxy, an adhesive tape, and a metal alloy.

7. A method as claimed in claim 2 wherein the transparent adhesive element is selected from the group consisting of silicon, polyimide epoxy, and adhesive tape.

8. A method as claimed in claim 2, comprising the additional step of bonding at least a first connecting electrical conductor between at least a first circuit contact on the optical semiconductor element and at least a first lead on the lead frame.

9. A method as claimed in claim 8, wherein the first connecting electrical conductor comprises a wire fabricated from a metal selected from the group consisting of gold, aluminum, and copper.

10. A method as claimed in claim 2, comprising the additional step of encapsulating the optical semiconductor element, the transparent adhesive element, and the aperture member with an encapsulating agent.

11. A method as claimed in claim 10, wherein the encapsulating agent is an epoxy molding compound.

12. A method comprising:
bonding a first optical semiconductor element to a first die paddle, the first optical semiconductor element having a first radiation-sensitive portion;
bonding a second optical semiconductor element to a second die paddle, the second optical semiconductor element having a second radiation-sensitive portion;
applying a first transparent adhesive element to at least the first radiation-sensitive portion;
applying a second transparent adhesive element to at least the second radiation-sensitive portion;
selecting a first aperture member, the first aperture member having at least a first characteristic;
applying the first aperture member to the first transparent adhesive element, the first aperture member selected and applied to the first transparent adhesive element by a programmable pick-and-place semiconductor assembly machine;
selecting a second aperture member, the second aperture member having at least a second characteristic, the second characteristic different from the first characteristic; and
applying the second aperture member to the second transparent adhesive element, the second aperture member selected and applied to the second transparent adhesive element by the programmable pick-and-place semiconductor assembly machine.

13. A method comprising:
using a bonding agent to attach an optical semiconductor element to a lead frame, the optical semiconductor element having an upper surface and a lower surface, the upper surface having a radiation-sensitive portion, the entire lower surface disposed within 1 mil of the lead frame when attached;
applying a transparent adhesive element to at least the radiation-sensitive portion;
selecting an aperture member; and
applying the aperture member to the transparent adhesive element.

14. A method comprising:
using a bonding agent to attach an optical semiconductor element to a lead frame, the optical semiconductor element having a radiation-sensitive portion;
applying a transparent adhesive element to at least the radiation-sensitive portion;
selecting an aperture member, the aperture member having a lower surface; and
applying the aperture member to the transparent adhesive element, the entire lower surface of the aperture member disposed within 1 mil of the radiation-sensitive portion when applied to the transparent adhesive element.
